(19) United States
(12) Patent Application Publication
(10) Pub. No.: US 2022/0367273 A1
(43) Pub. Date: Nov. 17, 2022

(54) ELEMENT CHIP MANUFACTURING METHOD AND SUBSTRATE PROCESSING METHOD

(71) Applicant: Panasonic Intellectual Property Management Co., Ltd., Osaka (JP)

(72) Inventors: Hidehiko KARASAKI, Hyogo (JP); Shogo OKITA, Hyogo (JP)

(21) Appl. No.: 17/661,584

(22) Filed: May 2, 2022

(30) Foreign Application Priority Data
May 13, 2021 (JP) 2021-081902

(51) Int. Cl. H01L 21/78; H01L 23/544

(52) U.S. Cl. CPC H01L 21/78; H01L 23/544; H01L 2223/5446; H01L 2223/54426

(57) ABSTRACT

A method including: a step of preparing a substrate that includes a first layer having a dicing region and a mark, and including a semiconductor layer, and a second layer including a metal film; a step of removing the metal film, to expose the semiconductor layer corresponding to a first region that corresponds to the mark; a step of smoothing a surface of the exposed semiconductor layer; a step of imaging the substrate, with a camera sensing predetermined electromagnetic waves, to detect a position of the mark through the semiconductor layer, and calculating a second region corresponding to the dicing region; and a step of removing the metal film, to expose the semiconductor layer corresponding to the second region. In the smoothing step, the surface of the semiconductor layer is smoothed so as to have a surface roughness of 1/4 or less of a wavelength of the predetermined electromagnetic waves.

### CROSS REFERENCE TO RELATED APPLICATION

The present application is based on and claims priority under 35 U.S.C. § 119 with respect to the Japanese Patent Application No. 2021-081902 filed on May 13, 2021, of which entire content is incorporated herein by reference into the present application.

### TECHNICAL FIELD

The present disclosure relates to an element chip manufacturing method and a substrate processing method.

### BACKGROUND

Element chips are usually manufactured by dicing a substrate including a semiconductor layer and the like. The substrate includes a plurality of element regions and a dicing region that defines the element regions. The substrate is diced by removing the semiconductor layer along the dicing region, into a plurality of element chips. Patent Literature 1 (JP 2013-535114) teaches to form groove-like gaps along the dicing region called streets by irradiation with laser beam, and then to expose the semiconductor layer to plasma, thereby to etch the semiconductor layer exposed from the gaps, and thus to dice the substrate.

With increasing technological development of electric vehicles (EVs) and the like, the demand for element chips called power devices has been increasing. Power devices, such as power MOSFET, are used mainly for power conversion and are required to be highly resistant to pressure and heat. To meet such requirements, devices that require heat dissipation therefrom represented by power devices are in some cases configured to allow current to flow in the thickness direction and include a metal film provided on the back surface side. Such element chips are obtained, for example, by dicing a substrate including a metal film and a semiconductor layer. However, especially when the metal film contains a high melting point metal, which is poor in reactivity, it is difficult to etch the metal film with plasma.

### SUMMARY

One aspect of the present disclosure relates to an element chip manufacturing method. The method includes: a preparation step of preparing a semiconductor substrate that includes a first layer having a first principal surface provided with a plurality of element regions, a dicing region defining the element regions, and an alignment mark, and a second layer laminated on the first layer and having a second principal surface opposite the first principal surface, wherein the first layer includes a semiconductor layer, and the second layer includes a metal film adjacent to the semiconductor layer; a first exposure step of irradiating a first laser beam that is absorbed into the metal film, from the second principal surface side to a first region that corresponds to the alignment mark on the second principal surface, to remove the metal film corresponding to the first region and expose the semiconductor layer corresponding to the first region; a smoothing step of smoothing a surface of the semiconductor layer corresponding to the first region exposed in the first exposure step; a calculation step of imaging the semiconductor substrate from the second principal surface side, with a camera capable of sensing electromagnetic waves passing through the semiconductor layer, to detect a position of the alignment mark through the semiconductor layer corresponding to the first region, and then calculating a second region that corresponds to the dicing region on the second principal surface, based on the detected position of the alignment mark; a second exposure step of irradiating a second laser beam to the second region from the second principal surface side, to remove the metal film corresponding to the second region and expose the semiconductor layer corresponding to the second region; and a dicing step of removing the exposed semiconductor layer corresponding to the second region, after the second exposure step, to dice the semiconductor substrate into a plurality of element chips, wherein in the smoothing step, the surface of the semiconductor layer corresponding to the first region exposed in the first exposure step is smoothed so as to have a surface roughness of ¼ or less of a wavelength of the electromagnetic waves.

Another aspect of the present disclosure relates to a substrate processing method. The method includes: a preparation step of preparing a semiconductor substrate that includes a first layer having a first principal surface provided with a plurality of element regions, a dicing region defining the element regions, and an alignment mark, and a second layer laminated on the first layer and having a second principal surface opposite the first principal surface, wherein the first layer includes a semiconductor layer, and the second layer includes a metal film adjacent to the semiconductor layer; a first exposure step of irradiating a first laser beam that is absorbed into the metal film, from the second principal surface side to a first region that corresponds to the alignment mark on the second principal surface, to remove the metal film corresponding to the first region and expose the semiconductor layer corresponding to the first region; a smoothing step of smoothing a surface of the semiconductor layer corresponding to the first region exposed in the first exposure step; a calculation step of imaging the semiconductor substrate from the second principal surface side, with a camera capable of sensing electromagnetic waves passing through the semiconductor layer, to detect a position of the alignment mark through the semiconductor layer corresponding to the first region, and then calculating a second region that corresponds to the dicing region on the second principal surface, based on the detected position of the alignment mark; a second exposure step of irradiating a second laser beam to the second region from the second principal surface side, to remove the metal film corresponding to the second region and expose the semiconductor layer corresponding to the second region; and an etching step of etching with plasma the exposed semiconductor layer corresponding to the second region, after the second exposure step, wherein in the smoothing step, the surface of the semiconductor layer corresponding to the first region exposed in the first exposure step is smoothed so as to have a surface roughness of ¼ or less of a wavelength of the electromagnetic waves.

According to the present disclosure, a semiconductor substrate including a metal film can be diced or etched with high precision.

### BRIEF DESCRIPTION OF THE DRAWINGS

FIG. 1 is a flowchart of an element chip manufacturing method according to an embodiment of the present disclosure.

FIG. 2A is a schematic top view of a semiconductor substrate according to an embodiment of the present disclosure, and FIG. 2B is a cross-sectional view of the semiconductor substrate of FIG. 2A taken along a line X-X.

FIG. 3 is a schematic top view of a conveying carrier and the semiconductor substrate held thereon.

FIG. 4 is a cross-sectional view taken along the line X-X in FIG. 2A of the semiconductor substrate after an attaching step according to an embodiment of the present disclosure.

FIG. 5 is a cross-sectional view taken along the line X-X in FIG. 2A of the semiconductor substrate after a protective film formation step according to an embodiment of the present disclosure.

FIG. 6 is a flowchart of an operation of a laser irradiator in a first exposure step according to an embodiment of the present disclosure.

FIGS. 7A and 7B are a cross-sectional view taken along the line X-X in FIG. 2A and a schematic top view, respectively, of the semiconductor substrate after the first exposure step according to the embodiment of the present disclosure.

FIG. 8 is a flowchart of an operation of the laser irradiator in a calculation step according to an embodiment of the present disclosure.

FIG. 9 is a cross-sectional view taken along the line X-X in FIG. 2A of the semiconductor substrate during the calculation step according to the embodiment of the present disclosure.

FIGS. 10A and 10B are a cross-sectional view taken along the line X-X in FIG. 2A and a schematic top view, respectively, of the semiconductor substrate after the second exposure step according to the embodiment of the present disclosure.

FIG. 11 is a cross-sectional view taken along the line X-X in FIG. 2A of the semiconductor substrate (element chips) after a dicing step according to an embodiment of the present disclosure.

FIG. 12 is a schematic sectional diagram of a plasma processing apparatus.

FIG. 13 is a block diagram of the plasma processing apparatus used in an embodiment of the present disclosure.

### DETAILED DESCRIPTION

A description will be given below of an embodiment of an element chip manufacturing method and a substrate processing method according to the present disclosure, by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

### (Element Chip Manufacturing Method)

An element chip manufacturing method according to the present disclosure includes a preparation step, a first exposure step, a smoothing step, a calculation step, a second exposure step, and a dicing step.

In the preparation step, a semiconductor substrate is prepared which includes a first layer including a semiconductor layer, and a second layer laminated on the first layer and including a metal film adjacent to the semiconductor layer. The first layer has a first principal surface provided with a plurality of element regions, dicing regions defining the element regions, and an alignment mark. The second layer has a second principal surface opposite the first principal surface. Here, the alignment mark is a mark that indicates the dicing regions or is provided for positioning.

In the first exposure step, a first laser beam is irradiated from the second principal surface side to a first region, to remove the metal film corresponding to the first region and expose the semiconductor layer corresponding to the first region. The first region is a region that corresponds to the alignment mark on the second principal surface of the second layer (e.g., a region on the back side of the alignment mark). The first laser beam is a laser beam that is absorbed into the metal film. The first laser beam may be a laser beam that passes through the semiconductor layer.

In the smoothing step, a surface of the semiconductor layer corresponding to the first region exposed in the first exposure step is smoothed. The smoothing may be done by various methods including a mechanical or chemical method.

In the calculation step, a position of the alignment mark is detected, and a second region that corresponds to the dicing regions on the second principal surface of the second layer is calculated, based on the detected position of the alignment mark. The detection of the position of the alignment mark can be done by imaging the semiconductor substrate, with a camera capable of sensing electromagnetic waves passing through the semiconductor layer. In this way, the alignment mark can be detected from the second principal surface side. That is, the camera and a laser irradiator can be arranged on the same surface side of the semiconductor substrate, which can simplify the apparatus configuration. For example, when the semiconductor layer is made of silicon, the electromagnetic waves that pass through the semiconductor layer may have a wavelength of 1100 nm or more and 6 μm or less.

In the second exposure step, a second laser beam is irradiated to the second region from the second principal surface side, to remove the metal film corresponding to the second region and expose the semiconductor layer corresponding to the second region. The second laser beam may be emitted by a similar mechanism and under similar conditions to those for the first laser beam.

In the dicing step, after the second exposure step, the exposed semiconductor layer corresponding to the second region is removed, to dice the semiconductor substrate into a plurality of element chips. The semiconductor layer may be removed by exposure to plasma.

In the above smoothing step, the surface of the semiconductor layer corresponding to the first region exposed in the first exposure step is smoothed so as to have a surface roughness of ¼ or less of the wavelength of the electromagnetic waves that pass through the semiconductor layer. For example, when the shortest wavelength of the electromagnetic waves is 1100 nm, the surface roughness to be achieved is set to 275 nm or less. Here, the surface roughness of the semiconductor layer means the maximum height roughness Rz. In the smoothing step, the surface of the semiconductor layer corresponding to the first region exposed in the first exposure step may be smoothed so as to have a surface roughness of ⅛ or less or 1/10 or less of the wavelength of the electromagnetic waves that pass through the semiconductor layer.

By sufficiently reducing the surface roughness of the semiconductor layer corresponding to the first region in this way, the camera can accurately detect the position of the alignment mark in the aforementioned calculation step. When the surface roughness of the semiconductor layer corresponding to the first region is small, the electromagnetic waves passing through the semiconductor layer are less likely to be scattered. Therefore, the alignment mark can be clearly imaged by the camera capable of sensing those electromagnetic waves. Once the position of the alignment mark can be accurately detected, the subsequent steps, i.e., the calculation of the second region, the exposure of the semiconductor layer corresponding to the second region, and the dicing of the semiconductor substrate, can be performed with high precision.

In the smoothing step, the surface of the semiconductor layer corresponding to the first region exposed in the first exposure step may be smoothed by exposing the surface to plasma. In other words, the surface may be smoothed by dry etching.

In the smoothing step, the surface of the semiconductor layer corresponding to the first region exposed in the first exposure step may be smoothed by striking particles against the surface. In other words, the surface may be smoothed by blasting.

In the smoothing step, the surface of the semiconductor layer corresponding to the first region exposed in the first exposure step may be smoothed by polishing the surface. The polishing may be buffing.

In the smoothing step, the surface of the semiconductor layer corresponding to the first region exposed in the first exposure step is smoothed by irradiating a third laser beam to the surface. The third laser beam may be, for example, a long pulse laser beam having a pulse width of several hundred nanoseconds to several milliseconds, and may be a laser beam shaped to have an intensity distribution in the plane orthogonal to the optical axis being a flat top distribution (top hat distribution).

The pulse width of the third laser beam may be larger than both the pulse width of the first laser beam and the pulse width of the second laser beam. By setting the pulse width as above, a favorable minute molten state can be formed on the surface of the semiconductor layer, and the unevenness of the surface of the semiconductor layer can be flattened (smoothed) by the action of surface tension.

The third laser beam preferably has a wavelength that is not absorbed into the metal film, and is absorbed into the semiconductor layer, but this is not essential. For example, when the semiconductor layer is made of silicon, the third laser beam may have a wavelength of 6 μm or more, and may be a carbon dioxide laser.

In the smoothing step, the surface of the semiconductor layer corresponding to the first region exposed in the first exposure step may be smoothed by bringing the surface into contact with a chemical solution that dissolves the semiconductor layer. Examples of such a chemical solution include a highly-concentrated methyl ethyl ketone solution and a highly-concentrated potassium hydroxide solution.

### (Substrate Processing Method)

A substrate processing method according to the present disclosure includes a preparation step, a first exposure step, a smoothing step, a calculation step, a second exposure step, and an etching step.

The preparation step, the first exposure step, the smoothing step, the calculation step, and the second exposure step may be the same as those in the above-described element chip manufacturing method.

In the etching step, after the second exposure step, the exposed semiconductor layer corresponding to the second region is etched with plasma. By this etching, grooves are formed in the semiconductor layer along the dicing regions. Similar to in the above-described element chip manufacturing method, the smoothing step serves to accurately detect the position of the alignment mark. Therefore, plasma etching of the semiconductor layer can be performed with high precision.

As described above, according to the present disclosure, a semiconductor substrate having a metal film can be diced or etched with high precision.

In the following, examples of the element chip manufacturing method and the substrate processing method according to the present disclosure will be specifically described with reference to the drawings. The steps as described above can be applied to the steps of the below-described examples of the element chip manufacturing method and the substrate processing method. The steps of the below-described examples of the element chip manufacturing method and the substrate processing method can be modified based on the description above. The matters as described below may be applied to the above embodiments. Of the steps of the below-described examples of the element chip manufacturing method and the substrate processing method, the steps which are not essential to the element chip manufacturing method and the substrate processing method according to the present disclosure may be omitted. The figures below are schematic and not intended to correctly reflect the shape and the number of the actual members.

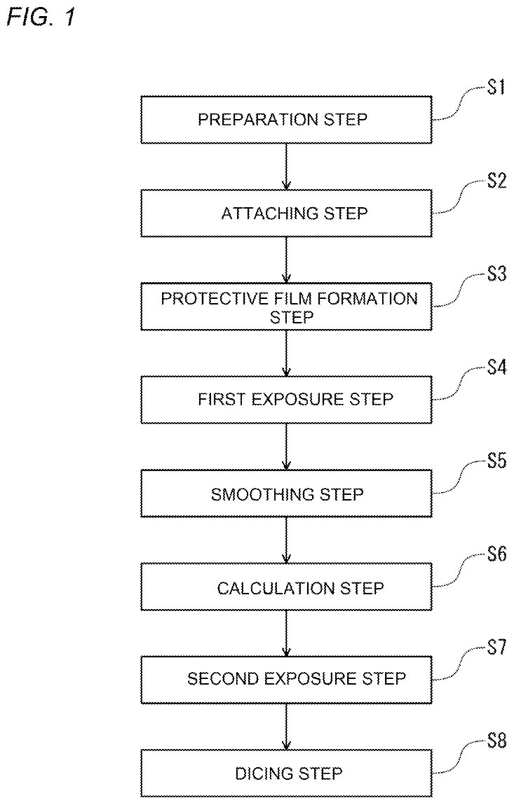

FIG. 1 is a flowchart of an element chip manufacturing method according to the present embodiment.

### (1) Preparation Step (S1)

First, a semiconductor substrate subjected to dicing is prepared.

### (Semiconductor Substrate)

The semiconductor substrate includes a first layer having a first principal surface provided with a plurality of element regions, dicing regions defining the element regions, and an alignment mark, and a second layer laminated on the first layer and having a second principal surface opposite the first principal surface. The first layer includes a semiconductor layer, and the second layer includes a metal film adjacent to the semiconductor layer.

The first layer may further include a wiring layer and an electrically insulating film on the first principal surface side. In this case, the semiconductor substrate corresponding to the element regions includes, for example, the wiring layer, the semiconductor layer, and the metal film. The semiconductor substrate corresponding to the dicing regions includes, for example, the insulating film, the semiconductor layer, and the metal film. The insulating film may contain a metal material, such as TEG (Test Element Group). Etching the semiconductor substrate in its thickness direction along the dicing regions can provide a plurality of element chips.

The semiconductor substrate may be of any size, and is, for example, about 50 mm or more and 300 mm or less in maximum diameter. The semiconductor substrate may be of any shape, and is, for example, circular, rectangular, or hexagonal. The semiconductor substrate may be provided with a cut, such as an orientation flat or a notch.

The semiconductor layer contains, for example, silicon (Si), gallium arsenide (GaAs), gallium nitride (GaN), or silicon carbide (SiC). The semiconductor layer in the element chip may have any thickness; the thickness may be, for example, 20 μm or more and 1000 μm or less, and may be 100 μm or more and 300 μm or less.

The wiring layer constitutes, for example, a semiconductor circuit, an electronic component element, or MEMS, and may include an electrically insulating film, a metal material, a resin layer (e.g., polyimide), a resist layer, an electrode pad, a bump, and others. The insulating film may be in the form of a laminate with a wiring metal material (multi-layer wiring layer or redistribution layer).

The shape of each dicing region may be set as appropriate according to a desired shape of element chips, without limited to a straight line shape, and may be, for example, a zig-zag shape or a wavy line shape. Note that the shape of element chips is, for example, rectangular or hexagonal.

The width of each dicing region may be set as appropriate depending on the size of the semiconductor substrate or the element chips, and others. The width of each dicing region is, for example, 10 μm or more and 300 μm or less. A plurality of the dicing regions may have the same width or different widths. Typically, a plurality of the dicing regions are formed on the semiconductor substrate. The pitch between the dicing regions adjacent to each other also is not limited, and may be set as appropriate depending on the size of the semiconductor substrate or the element chips, and others.

The alignment mark is provided on the first principal surface, for positioning of the semiconductor substrate. The alignment mark is not limited, but may be a mark indicating the boundaries between the dicing regions and the element regions (e.g., a metal pattern called a seal or seal ring, a pattern formed of an electrically insulating material called a scribe line), and may be a mark especially provided for positioning. The alignment mark can be usually distinguished from the semiconductor layer and the wiring layer by image recognition. The alignment mark may be of any shape. The shape of the alignment mark may be a combination of straight lines (e.g., parallel lines, grid pattern lines), and may be, for example, a cross shape, a circle shape, or a rectangle shape. The alignment mark other than the boundary line is provided, for example, in an outer peripheral portion of the semiconductor substrate within the dicing regions. The alignment mark may be provided somewhere in the element regions, as needed.

The metal film is formed nearer the second principal surface side than the semiconductor layer is, in order to, for example, allow current to flow in the thickness direction, and improve heat dissipation. The metal film is preferably disposed at the outermost layer on the second principal surface side. The metal film and the semiconductor layer are disposed adjacent to each other, but not limited thereto, another layer, such as an adhesive layer, may be interposed therebetween. Examples of the material of the metal film include silver, copper, aluminum, an aluminum alloy, tungsten, nickel, gold, platinum, and titanium. The metal film is, for example, vapor-deposited or attached onto the semiconductor layer. The metal film may be a single layer film, and may be a multilayer film. The metal film may be, for example, obtained by laminating titanium, nickel and gold in this order on the semiconductor layer (Au/Ni/Ti), or laminating titanium, nickel and silver in this order on the semiconductor layer (Ag/Ni/Ti), or laminating titanium, nickel and aluminum alloy in this order on the semiconductor layer (Al alloy/Ni/Ti).

The thickness of the metal film (total thickness) is not limited, and may be set as appropriate according to the use of the element chips. The thickness of the metal film is, for example, 50 nm or more and 100 μm or less. When the metal film is a laminate of Au/Ni/Ti, for example, the Au film thickness is 50 nm or more and 200 nm or less, the Ni film thickness is 200 nm or more and 400 nm or less, and the Ti film thickness is 100 nm or more and 300 nm or less. When the metal film is a laminate of Ag/Ni/Ti, for example, the Ag film thickness is 200 nm or more and 30 μm or less, the Ni film thickness is 200 nm or more and 400 nm or less, and the Ti film thickness is 100 nm or more and 300 nm or less. When the metal film is a laminate of Al alloy/Ni/Ti, for example, the Al-alloy film thickness is 200 nm or more and 30 μm or less, the Ni film thickness is 200 nm or more and 400 nm or less, and the Ti film thickness is 100 nm or more and 300 nm or less.

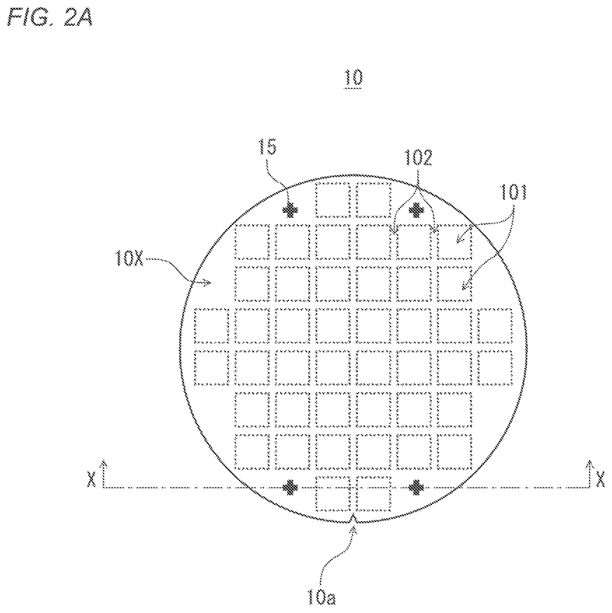

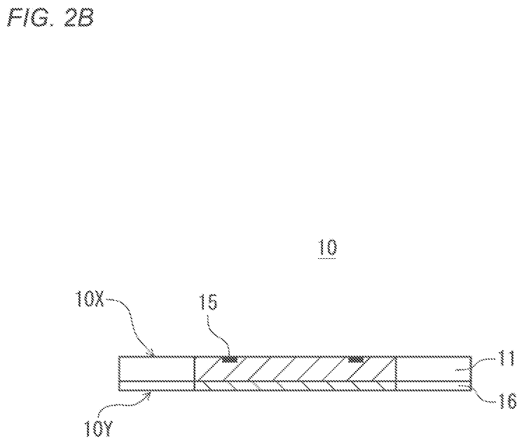

FIG. 2A is a schematic top view of a semiconductor substrate seen from the first principal surface side. FIG. 2B is a cross-sectional view of the semiconductor substrate of FIG. 2A taken along the line X-X.

A semiconductor substrate 10 includes: a first layer having a first principal surface 10X provided with a plurality of element regions 101, dicing regions 102 defining the element regions 101, and an alignment mark 15; and a second layer laminated on the first layer and having a second principal surface 10Y opposite the first principal surface 10X. The first layer includes a semiconductor layer 11, and the second layer includes a metal layer 16 adjacent to the semiconductor layer 11. On the outer periphery of the first principal surface 10X, four alignment marks 15 each having a cross shape are provided. The semiconductor substrate 10 has one notch 10a.

### (2) Attaching Step (S2)

After the preparation step and before a first exposure step, the semiconductor substrate may be attached at the first principal surface to a holding sheet. This increases the ease of handling of the semiconductor substrate.

### (Holding Sheet)

The holding sheet may be secured to a frame. This can further increase the ease of handling. The semiconductor substrate is subjected to each step, for example, in a state of being held by a conveying carrier including a frame and a holding sheet secured to the frame.

The frame is a frame member having an opening equal to or greater in area than the whole semiconductor substrate, and has a predetermined width and a substantially consistent thin thickness. The frame has such a rigidity that it can be conveyed with the holding sheet and the semiconductor substrate held thereon. The opening of the frame may be of any shape, for example, a circular shape or a polygonal shape, such as a rectangular or hexagonal shape. The frame may be made of, for example, a metal, such as aluminum or stainless steel, or a resin.

The holding sheet may be made of any material. For easy attachment of the semiconductor substrate thereto, the holding sheet preferably includes an adhesive layer and a non-adhesive layer with flexibility.

The non-adhesive layer may be made of any material, for example, polyolefin such as polyethylene and polypropylene, polyester such as polyvinyl chloride and polyethylene terephthalate, and other thermoplastic resins. The resin film may include a rubber component for adding elasticity (e.g., ethylene-propylene rubber (EPM), ethylene-propylene-diene rubber (EPDM)), and various additives, such as a plasticizer, a softener, an antioxidant, and an electrically conductive material. The thermoplastic resin may have a functional group that reacts during photopolymerization reaction, such as an acryl group. The non-adhesive layer may have any thickness; the thickness is, for example, 50 μm or more and 300 μm or less, preferably 50 μm or more and 150 μm or less.

The holding sheet is attached at its periphery to the frame, with the side where the adhesive layer is disposed (adhesive side) in contact with the frame, to cover the opening of the frame. On the adhesive side exposed from the opening of the frame, the semiconductor substrate is attached, with one of its principal surfaces (first principal surface) in contact with the adhesive side. The semiconductor substrate is thus held on the holding sheet. The semiconductor substrate may be held on the holding sheet via a die attach film (DAF).

The adhesive layer is preferably made of an adhesive component, the adhesive strength of which is reduced by ultraviolet (UV) irradiation. In picking up the element chips after dicing, the element chips can be easily peeled off from the adhesive layer by UV irradiation, which eases the pickup. The adhesive layer can be obtained by, for example, applying a UV curing acrylic adhesive on one side of the non-adhesive layer, in a thickness of 5 μm or more and 100 μm or less (preferably 5 μm or more and 15 μm or less).

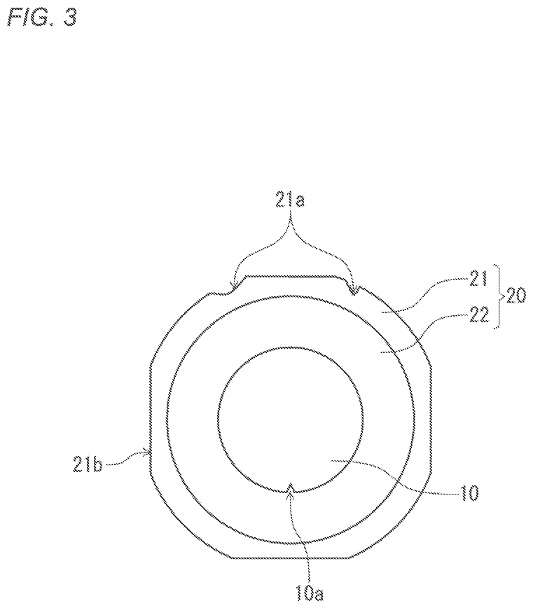

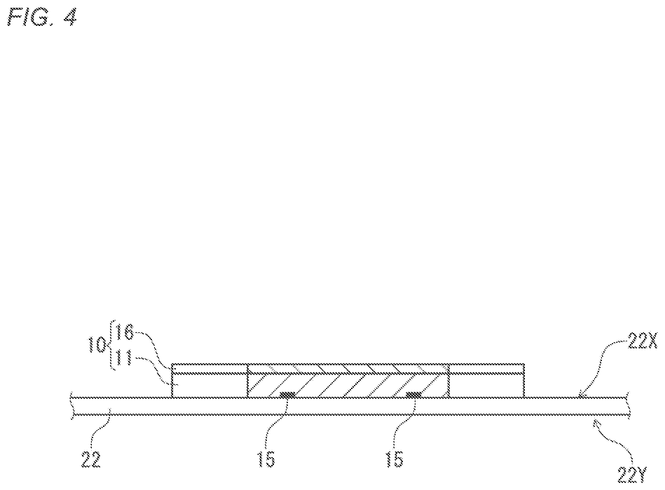

FIG. 3 is a schematic top view of the conveying carrier and the semiconductor substrate held thereon. FIG. 4 is a cross-sectional view taken along the line X-X in FIG. 2A of the semiconductor substrate after the attaching step according to the present embodiment. A conveying carrier 20 includes a frame 21 and a holding sheet 22 secured to the frame 21. The frame 21 may be provided with a notch 21a and a corner cut 21b for correct positioning. An adhesive side 22X of the holding sheet 22 is attached at its periphery to one side of the frame 21, and on the adhesive side 22X exposed from the opening of the frame 21, one of the principal surfaces of the semiconductor substrate 10 is attached. In plasma processing, the holding sheet 22 is placed on a stage in a plasma processing apparatus, such that a non-adhesive side 22Y opposite the adhesive side 22X comes in contact with the stage.

### (3) Protective Film Formation Step (S3)

When the dicing step is performed using plasma, it is desirable to form a protective film so as to cover the second principal surface of the semiconductor substrate. The protective film protects the metal film corresponding to the element regions, from the plasma. The protective film corresponding to the first region is removed, together with the metal film, in a first exposure step. The protective film corresponding to the second region is removed, together with the metal film, in a second exposure step.

### (Protective Film)

The protective film includes a resist material, such as a thermosetting resin (e.g., polyimide), a photoresist (e.g., phenol resin), or a water-soluble resist (e.g., acrylic resin). The protective film can be formed by, for example, forming a resist material into a sheet and attaching the sheet to the second principal surface, or by applying a liquid raw material of a resist material onto the second principal surface using a spin-coating or spray-coating technique.

The protective film may have any thickness, but is preferably thick enough not to be completely removed in the plasma dicing step. The thickness of the protective film is set, for example, to be equal to or greater than a calculated amount (thickness) of the protective film to be etched in the plasma dicing step.

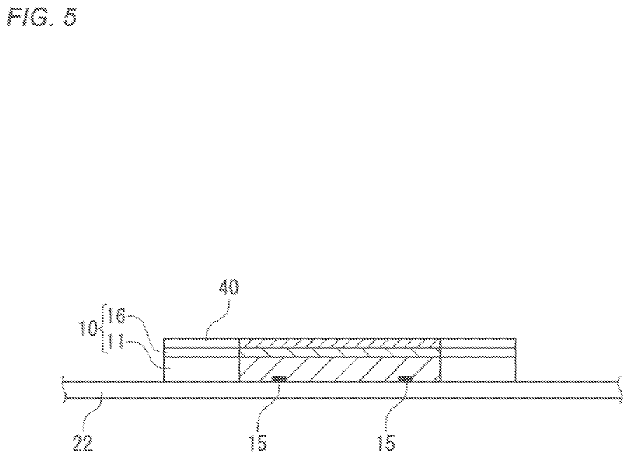

FIG. 5 is a cross-sectional view taken along the line X-X in FIG. 2A of the semiconductor substrate after the protective film formation step according to the present embodiment. A protective film 40 is formed so as to cover the metal film 16 of the semiconductor substrate 10.

### (4) First Exposure Step (S4)

A first laser beam that is absorbed into the metal film irradiated to a region (first region) corresponding to the alignment mark on the second principal surface. This removes the protective film and the metal film corresponding to the first region and exposes the semiconductor layer corresponding to the first region.

### (First Region)

The first region is determined, for example, from the position of a cut, such as an orientation flat or notch, provided on the semiconductor substrate, or from the position of a cut, such as a corner cut or notch, provided on the frame, with reference to design information, such as a design drawing. The design information shows the positional relationship between each cut and the alignment mark. A part of the second principal surface which is corresponding to the alignment mark determined from the position of the cut is referred to as the first region. In other words, at least part of the alignment mark and at least part of the first region face each other, and when seen from the direction normal to the second principal surface, at least part of the alignment mark overlaps the first region.

The position of the alignment mark determined as described above with reference to design information may sometimes deviate from the actual position thereof, due to variations in the size of the substrate, variations in the formed position of the alignment mark, and others. The deviation, however, is permissible if it is about several hundred μm. Here, a relatively wide area corresponding to the alignment mark is defined as the first region on the second principal surface.

When the alignment mark is the boundary line, the first region includes part of at least two boundary lines (e.g., an intersection of grid-pattern boundary lines, part of two adjacent parallel lines). The first region as above has, for example, an arc or annular shape along the outer periphery of the semiconductor substrate. In the case of the alignment mark other than the boundary line, the whole alignment mark as seen from the direction normal to the second principal surface overlaps the first region. In this case, given that the smallest circle that surrounds the alignment mark other than the boundary line is drawn, a circular or rectangular area overlapping the circle and having a diameter (or a longitudinal side length) about 5 to 10 times as large as that of the circle can be determined as the first region.

The first region is preferably determined such that the metal film does not enter the field of view of the camera used in the calculation step. This is to avoid misidentifying the metal film as the alignment mark. For example, when the diameter of the above smallest circle is 100 μm, provided that the field of view of the camera is 300 μm square, the diameter of the first region (or a longitudinal side length) is about 500 μm.

### (First Laser Beam)

The first laser beam preferably passes through the semiconductor layer, while being absorbed into the metal film. In this case, the metal film can be removed by the irradiation of the first laser beam, whereas in the semiconductor layer underlying the metal film, the surface is unlikely to be roughened, and the interior crystal structure is unlikely to be disordered by the irradiation.

In view of suppressing the damage to the semiconductor layer, the first laser beam is preferably to have a wavelength hardly absorbed into the semiconductor constituting the semiconductor layer. For example, when the semiconductor layer is a silicon layer, the first laser beam preferably has a wavelength of 1100 nm or more and 6 μm or less, and may be, for example, a carbon monoxide laser. The wavelength of the first laser beam is not limited to of the above wavelength range, and may be of a shorter wavelength range, which advantageously has excellent light-collecting ability. Specifically, the first laser beam may have a wavelength of 850 nm or more and 1100 nm or less, and may have a wavelength of 190 nm or more and 450 nm or less. More specifically, the wavelength of the first laser beam may be 980 nm, 1064 nm, or 1030 nm in the near infrared region, or may be 355 nm, 305 nm, 308 nm, or 266 nm in the ultraviolet region.

The first laser beam may have any frequency; the frequency is, for example, 1 kHz or more and 200 kHz or less. The first laser beam may be emitted by any laser oscillation mechanism. Examples of the first laser include: a semiconductor laser using a semiconductor as a laser oscillation medium; a gas laser using a gas, such as carbon dioxide (CO₂), as the medium; a solid laser using YAG; and a fiber laser. Any laser oscillator may be used for laser emission. Preferred is a pulse laser oscillator that emits a pulse laser beam, in terms of its low thermal impact on the semiconductor substrate.

The laser beam may have any pulse width. In view of reducing the thermal impact and preventing the damage to the semiconductor layer, the pulse width is preferably 500 nanoseconds or less, more preferably 200 nanoseconds or less. Particularly preferred is an ultrashort pulse laser beam having a pulse width ranging from several femtoseconds (1·10⁻¹⁵ sec) or several hundred femtoseconds (100·10⁻¹⁵ sec) to 100 picoseconds (100·10⁻¹² sec).

The laser irradiator includes: for example, an arm for delivering a semiconductor substrate; a stage for supporting the semiconductor substrate; an irradiation head for irradiating a laser beam; a driving unit for driving the stage; an input unit for receiving input data related to the dicing regions, the first region and/or the alignment mark; an imaging unit for imaging the semiconductor substrate supported on the stage; an image processing unit for detecting the shape etc. of the imaged semiconductor substrate; an arithmetic unit for determining the position of the semiconductor substrate, the first region and/or the second region, based on the input data and the shape etc. of the semiconductor substrate detected by the image processing unit; and a control unit for controlling these operations.

The input unit includes, for example, a touch panel. For example, an operator inputs various data into the input unit. The control unit, the image processing unit and the arithmetic unit include, for example, a computer. The imaging unit includes a camera. The driving unit includes, for example, a ball screw and a linear guide system. The rotation of the ball screw moves the stage translationally and/or vertically under the irradiation head and the camera.

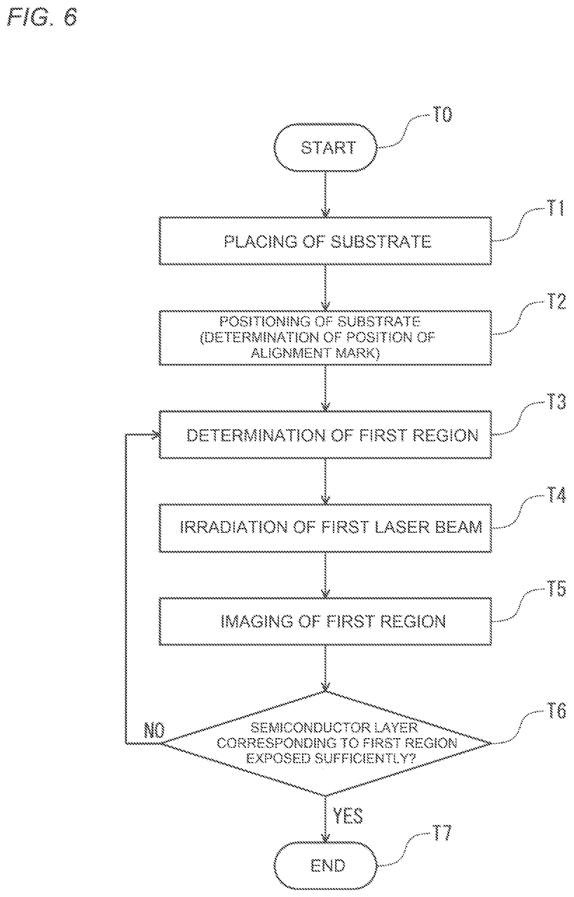

FIG. 6 is a flowchart of an operation of a laser irradiator in the first exposure step according to the present embodiment.

Upon inputting of necessary data into the input unit, the operation in the first exposure step of the laser irradiator starts (T0). A semiconductor substrate delivered into the laser irradiator is passed onto the arm and placed on the stage (T1). The stage is provided with a protrusion at a position corresponding to the cut in the semiconductor substrate or in the frame, and thus, the semiconductor substrate can be positioned on the stage. Alternatively, after placed on the stage, the semiconductor substrate may be imaged, so that the position of the cut can be detected with the image processing unit. In this case, after the detection of the position of the cut, the arithmetic unit calculates where the semiconductor substrate is to be positioned on the stage. Upon positioning of the semiconductor substrate on the stage, the arithmetic unit determines the position of the alignment mark with reference to the data in the input unit (T2).

The arithmetic unit further determines the position of the outer periphery or center of the first region, based on the position of the alignment mark (T3). The information, such as the size and shape, of the first region is input in advance in the input unit. Alternatively, the information, such as the size and shape, of the alignment mark may be input in advance in the input unit, so that the arithmetic unit can calculate an appropriate first region.

The driving unit drives the stage, to move the determined outer periphery or center of the first region under the irradiation head. When the semiconductor substrate is placed at a predetermined position under the irradiation head, an irradiation unit starts irradiation of the first laser beam (T4). Under irradiation of the first laser beam, the driving unit further drives the stage to move in the plane direction, based on the input information, such as the size and shape, of the first region. This removes the protective film and the metal film corresponding to the first region.

After a series of processes is completed, the first region may be imaged from above (T5). If a predetermined information (e.g., data showing that the semiconductor layer corresponding to the first region has been fully exposed) cannot be collected from the processed image of the alignment mark (T6), the processing subsequent to the determination of the position of the first region (T3 to T5) may be performed again. Thereafter, the operation in the first exposure step of the laser irradiator ends (T7).

When two or more alignment marks are provided, a series of these processes may be performed for each of the alignment marks. In this case, the driving unit may be driven to move the semiconductor substrate under the camera included in the imaging unit, so that the camera can take images of the alignment marks one after another.

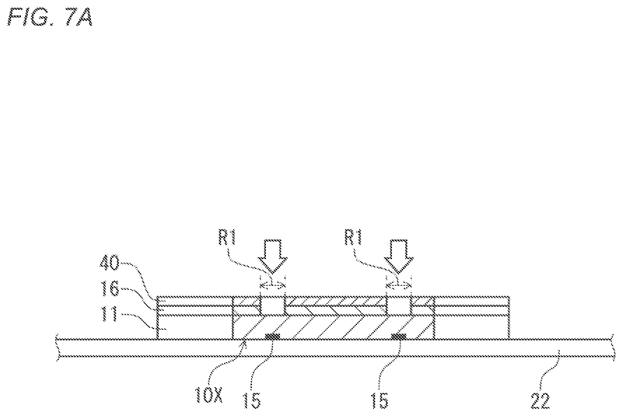

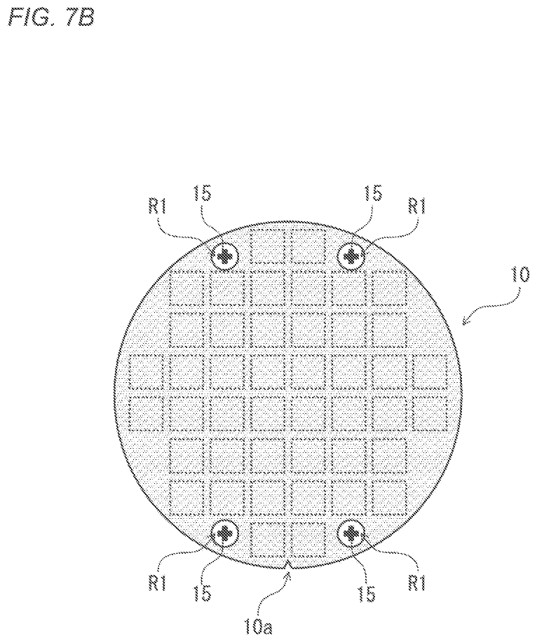

FIG. 7A is a cross-sectional view taken along the line X-X in FIG. 2A, of the semiconductor substrate after the first exposure step according to the present embodiment. FIG. 7B is a schematic top view of the semiconductor substrate after the first exposure step according to the present embodiment. Four alignment marks 15 are provided on the first principal surface 10X of the semiconductor substrate 10. The protective film 40 and the metal film 16 corresponding to a first region R1 are removed at four places, so that each alignment mark 15 becomes entirely exposed. The first region R1 is a circular region surrounding each alignment mark 15. In FIG. 7B, the protective film 40 is shown by hatching for the sake of convenience.

### (5) Smoothing Step (S5)

The surface of the semiconductor layer corresponding to the first region exposed in the first exposure step is smoothed. The surface of the semiconductor layer corresponding to the first region exposed in the first exposure step is smoothed so as to have a surface roughness of ¼ or less of a wavelength of the electromagnetic waves used in a calculation step that pass through the semiconductor layer.

In the present embodiment, the surface of the semiconductor layer corresponding to the first region is smoothed by polishing (e.g., buffing) the surface, but not limited thereto. For example, the surface of the semiconductor layer corresponding to the first region may be smoothed by exposing the surface to plasma (dry etching), by striking particles against the surface (blasting), by irradiating a third laser beam to the surface (laser annealing), or by bringing the surface into contact with a chemical solution that dissolves the semiconductor layer (e.g., a methyl ethyl ketone solution or a potassium hydroxide solution).

### (6) Calculation Step (S6)

The semiconductor substrate is imaged from the second principal surface side with a camera capable of sensing electromagnetic waves passing through the semiconductor layer, to detect the position, shape, etc. of the alignment mark through the semiconductor layer corresponding to the first region. A second region that corresponds to the dicing regions on the second principal surface is calculated, based on the detected data related to the alignment mark.

### (Camera)

The camera is capable of sensing electromagnetic waves passing through the semiconductor layer. It is therefore possible to image the alignment mark through the semiconductor layer corresponding to the first region from the second principal surface side. The electromagnetic waves that pass through the semiconductor layer may be generated by, for example, a near-infrared halogen lamp arranged on the second principal surface side and having a peak wavelength of 1000 nm or more.

The camera may be, for example, an infrared camera capable of sensing electromagnetic waves in the near-infrared region (wavelength range: 750 nm to 1200 nm), but is preferably an infrared camera having a sensitivity in a longer wavelength region. The infrared camera constitutes the imaging unit. The imaging unit may include a camera other than the infrared camera (e.g., a camera capable of sensing visible light). The imaging unit may include a plurality of infrared cameras. The field of view of the infrared camera is not limited, but may be 300 μm square or more, in view of improving the precision.

### (Second Region)

The second region is calculated from the detected position of the alignment mark and the data in the input unit. The second region is part of the second principal surface corresponding to the dicing regions. In other words, at least part of the dicing regions and at least part of the second region face each other, and when seen from the direction normal to the second principal surface, at least the part of the dicing regions overlaps the second region. Preferably, the dicing regions entirely overlap the second region.

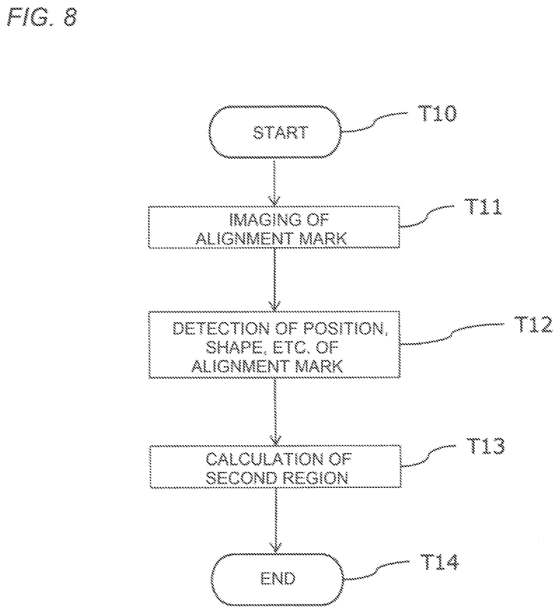

FIG. 8 is a flowchart of an operation of the laser irradiator in the calculation step according to the present embodiment.

Upon completion of the first exposure step, the operation of the laser irradiator in the calculation step starts (T10). The driving unit drives the stage, to move the first region under the infrared camera. The imaging unit captures an image of the alignment mark through the semiconductor layer corresponding to the first region, from the second principal surface side, with the infrared camera (T11). The image processing unit processes the captured image, to detect the position, shape, etc. of the alignment mark (T12). The arithmetic unit calculates the position of the dicing regions on the second principal surface, based on the detected data related to the alignment mark and the input data related to the dicing regions (T13). This determines the second region that corresponds to the dicing regions on the second principal surface. Thereafter, the operation of the laser irradiator in the calculation step ends (T14).

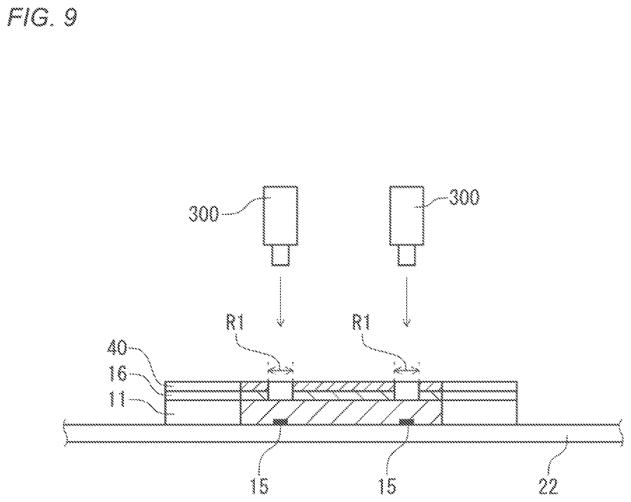

FIG. 9 is a cross-sectional view taken along the line X-X in FIG. 2A of the semiconductor substrate during the calculation step according to the present embodiment. An infrared camera 300 captures an image of the alignment mark 15 through the semiconductor layer 11 corresponding to the first region R1. The captured image is processed, and the shape etc. of the alignment mark 15 are detected. Based on the detected shape etc. of the alignment mark 15, the position of the dicing regions is calculated.

### (7) Second Exposure Step (S7)

A second laser beam is irradiated to the second region from the second principal surface side, to remove the protective film and the metal film corresponding to the second region. As a result, the semiconductor layer corresponding to the second region is exposed.

The driving unit drives the stage, to move the end of semiconductor substrate under the irradiation head. When the semiconductor substrate is placed at a predetermined position, the irradiation unit starts irradiation of the second laser beam to the second region. Under irradiation of the second laser beam, the driving unit further drives the stage to move in the plane direction, based on the size, shape, etc. of the second region. This removes the protective film and the metal film corresponding to the second region.

The second laser beam may be emitted by a similar mechanism and under similar conditions to those of the first laser beam. Especially when the second laser beam is an ultrashort pulse laser beam, the damage on the semiconductor layer can be suppressed, and a desired plasma etching is likely to be achieved.

After the second exposure step, a fourth laser beam may be irradiated to the exposed semiconductor layer, to improve the smoothness of the semiconductor layer. The fourth laser beam may be, for example, a long pulse laser beam having a pulse width of several hundred nanoseconds to several milliseconds, and may be a laser beam shaped to have an intensity distribution in the plane orthogonal to the optical axis being a flat top distribution (top hat distribution).

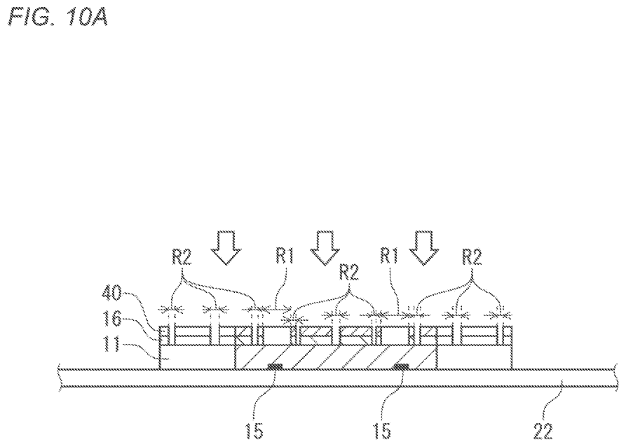

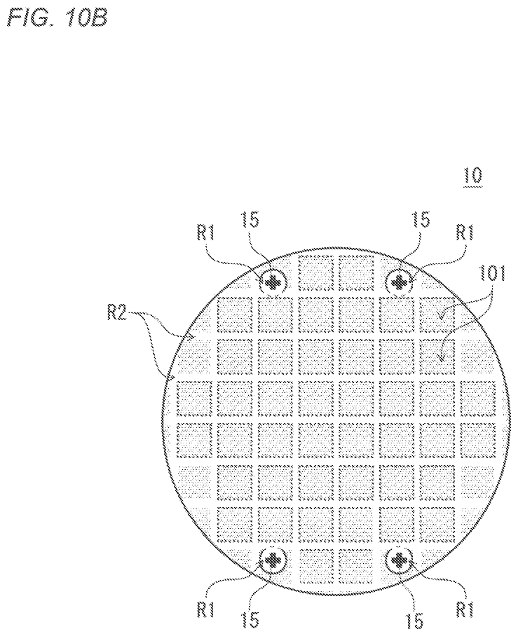

FIG. 10A is a cross-sectional view taken along the line X-X in FIG. 2A of the semiconductor substrate after the second exposure step according to the present embodiment. FIG. 10B is a schematic top view of the semiconductor substrate after the second exposure step according to the present embodiment. The protective film 40 and the metal film 16 corresponding to a second region R2 are further removed, and the semiconductor layer 11 corresponding to the second region R2 is exposed. In FIG. 10B, the protective film 40 is shown by hatching for the sake of convenience.

### (8) Dicing Step (S8)

The exposed semiconductor layer corresponding to the second region is removed, so that the semiconductor substrate is diced into a plurality of element chips. The dicing step can be performed by applying a plasma (first plasma) to the second region from the second principal surface side.

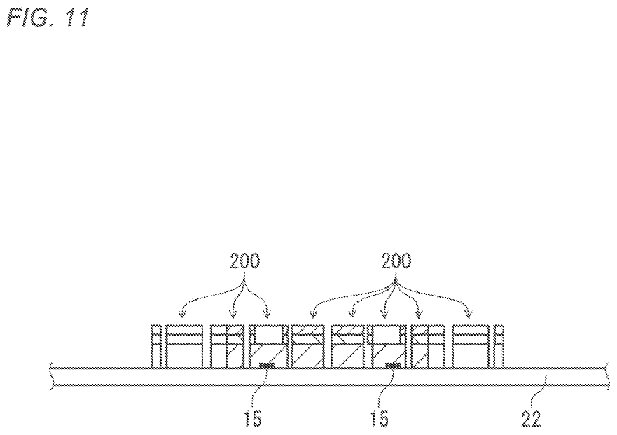

FIG. 11 is a cross-sectional view taken along the line X-X in FIG. 2A of the semiconductor substrate after the dicing step according to the present embodiment. The semiconductor layer 11 corresponding to the second region R2 is removed, forming a plurality of element chips 200.

Prior to the dicing step, a step of cleaning the second principal surface with a second plasma may be performed. The second plasma is usually generated under the conditions different from those for generating the first plasma when performing dicing. The cleaning step is performed for the purpose of, for example, reducing the residue caused by the first exposure step and/or the second exposure step. This can improve the quality of the plasma dicing.

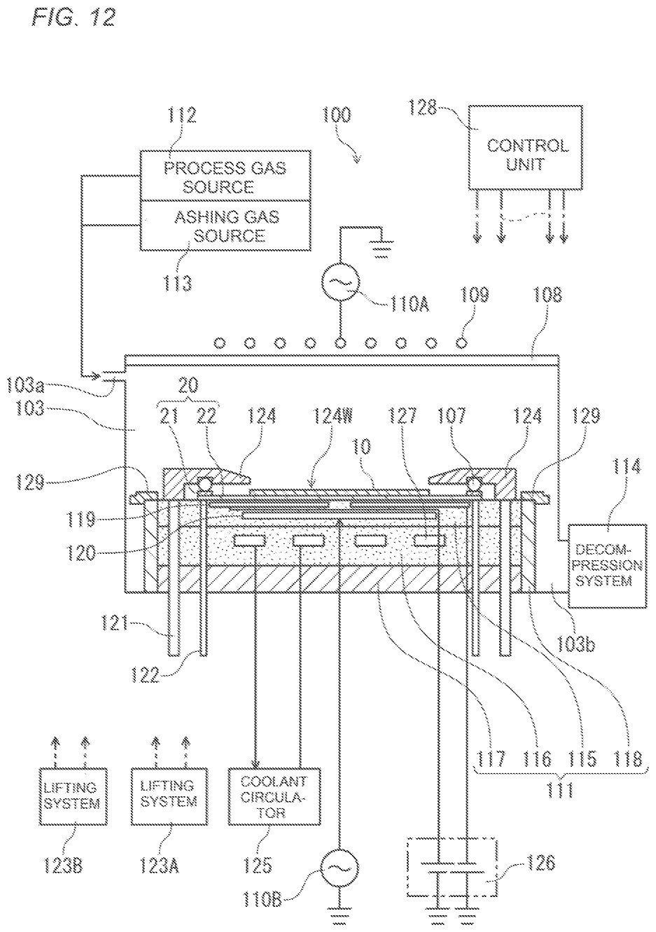

Next, an embodiment of a plasma processing apparatus used in the dicing step will be specifically described. FIG. 12 is a schematic cross-sectional diagram of a plasma processing apparatus. In FIG. 12, the semiconductor substrate is held on the conveying carrier. The structure of the plasma processing apparatus is not limited thereto.

### (Plasma Processing Apparatus)

A plasma processing apparatus 100 includes a stage 111. A conveying carrier 20 is set on the stage 111, with the surface holding a semiconductor substrate 10 of a holding sheet 22 faced upward. The stage 111 has such a size that the whole conveying carrier 20 can be seated thereon. Above the stage 111, a cover 124 having a window 124W for exposing at least part of the semiconductor substrate 10 therefrom is arranged. The cover 124 is provided with pressing members 107 for pressing the frame 21 downward while the frame 21 is on the stage 111. The pressing members 107 are preferably a member that can achieve point contact with the frame 21 (e.g., a coil spring or an elastic resin). This can correct the distortion of the frame 21, while restricting the thermal communication between the frame 21 and the cover 124.

The stage 111 and the cover 124 are arranged in a vacuum chamber 103. The vacuum chamber 103 is approximately cylindrical with the top open. The open top is closed by a dielectric member 108 serving as a lid. Examples of the constituent material of the vacuum chamber 103 include aluminum, stainless steel (SUS), and aluminum with anodic oxide coating. Examples of the constituent material of the dielectric member 108 include yttrium oxide (Y₂O₃), aluminum nitride (AlN), alumina (Al₂O₃), quartz (SiO₂), and other dielectric materials. Above the dielectric member 108, a first electrode 109 serving as an upper electrode is arranged. The first electrode 109 is electrically connected to a first high-frequency power source 110A. The stage 111 is positioned on the bottom side in the vacuum chamber 103.

The vacuum chamber 103 is provided with a gas inlet 103a and a gas outlet 103b. The gas inlet 103a is connected to plasma-generating gas (process gas) supply sources, i.e., a process gas source 112 and an ashing gas source 113, each through a conduit. The gas outlet 103b is connected to a decompression system 114 including a vacuum pump for exhausting the gas within the vacuum chamber 103 to reduce the pressure therein. While a process gas is introduced into the vacuum chamber 103, the first electrode 109 is supplied with a high-frequency power from the first high-frequency power source 110A. A plasma is thus generated in the vacuum chamber 103.

The stage 111 includes an electrode layer 115, a metal layer 116, and a base table 117 supporting the electrode layer 115 and the metal layer 116, each being approximately circular. The stage 111 further includes a peripheral member 118 surrounding the electrode layer 115, the metal layer 116, and the base table 117. The peripheral member 118 is formed of a metal having electrical conductivity and etching resistance, and serves to protect the electrode layer 115, the metal layer 116, and the base table 117 from plasma exposure. On the top surface of the peripheral member 118, an annular circumferential ring 129 is provided. The circumferential ring 129 serves to protect the top surface of the peripheral member 118 from plasma exposure. The electrode layer 115 and the circumferential ring 129 are formed of, for example, the dielectric material as listed above.

Within the electrode layer 115, an electrode for electrostatic chucking (hereinafter, ESC electrode 119), and a second electrode 120 electrically connected to a second high-frequency power source 110B are disposed. The ESC electrode 119 is electrically connected to a DC power source 126. The ESC electrode 119 and the DC power source 126 constitute an electrostatic chuck system. The electrostatic chuck system pulls the holding sheet 22 onto the stage 111 and secures it thereto. Although a description will be made below of a case where the electrostatic chuck system is used as a securing system for securing the holding sheet 22 to the stage 111, this should not be taken as a limitation. A clamp (not shown) may be used for securing the holding sheet 22 to the stage 111.

The metal layer 116 is formed of, for example, aluminum with an anodic oxidation coating. The metal layer 116 contains a coolant channel 127 configured to cool the stage 111. By cooling the stage 111, the holding sheet 22 set on the stage 111 is cooled down, and the cover 124 partially in contact with the stage 111 is also cooled down. This protects the semiconductor substrate 10 and the holding sheet 22 from being damaged by being heated during plasma processing. A coolant in the coolant channel 127 is circulated by a coolant circulator 125.

Around the peripheral portion of the stage 111, a plurality of support members 122 extending through the stage 111 are provided. The support members 122 support the frame 21 of the conveying carrier 20. The support members 122 are driven by a first lifting system 123A, and move upward and downward. The conveying carrier 20 having delivered into the vacuum chamber 103 is passed onto the support members 122 at a predetermined raised position. Then the support members 122 descend until their top surfaces become flush with or lower than the top surface of the stage 111, which sets the conveying carrier 20 at a predetermined position on the stage 111.

A plurality of lifting rods 121 are coupled to the peripheral edge of the cover 124, to lift and lower the cover 124. The lifting rods 121 are driven by a second lifting system 123B. The lifting and lowering operation of the cover 124 by the second lifting systems 123B can be controlled independently from the operation by the first lifting system 123A.

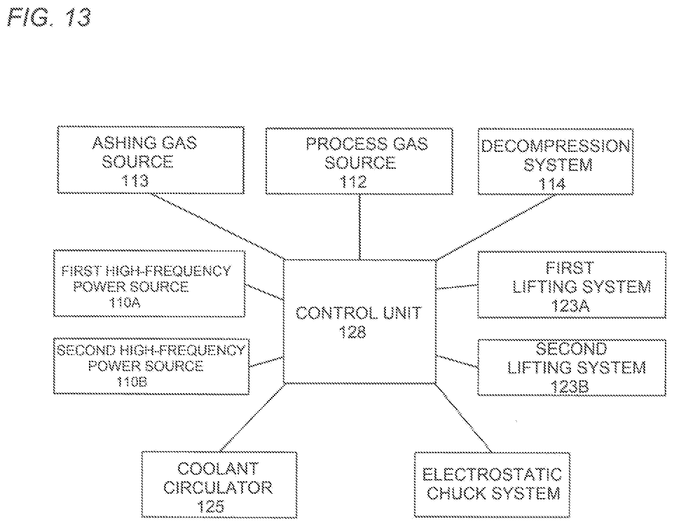

A control unit 128 is configured to control operations of component elements of the plasma processing apparatus 100 including the first high-frequency power source 110A, the second high-frequency power source 110B, the process gas source 112, the ashing gas source 113, the decompression system 114, the coolant circulator 125, the first and second lifting systems 123A and 123B, and the electrostatic chuck system. FIG. 13 is a block diagram of the plasma processing apparatus used in the present embodiment.

After the conveying carrier 20 holding the semiconductor substrate 10 is delivered into the vacuum chamber 103, the semiconductor substrate 10 is subjected to etching while being seated on the stage 111. In delivering the semiconductor substrate 10, within the vacuum chamber 103, the cover 124 is lifted to a predetermined position by means of the lifting rods 121. A gate valve (not shown) opens to allow the conveying carrier 20 to be delivered into the vacuum chamber 103. The support members 122 are on standby at a raised position. When the conveying carrier 20 reaches a predetermined position above the stage 111, the conveying carrier 20 is passed onto the support members 122. The conveying carrier 20 is placed onto the support members 122, with the adhesive side 22X of the holding sheet 22 faced upward.

After the conveying carrier 20 is passed onto the support members 122, the vacuum chamber 103 is closed in a hermetically sealed state. Next, the support members 122 start descending. When the support members 122 have descended until their top surfaces become flush with or lower than the top surface of the stage 111, the conveying carrier 20 is set on the stage 111. Then the lifting rods 121 are driven to lower the cover 124 to a predetermined position. The distance between the cover 124 and the stage 111 is adjusted so that the pressing members 107 in the cover 124 each come in point-contact with the frame 21. In this way, the frame 21 is pressed downward by the pressing members 107 and is covered with the cover 124, with at least part of the semiconductor substrate 10 exposed from the window 124W.

The cover 124 has, for example, a doughnut-like shape with approximately circular contour and has a consistent width and thin thickness. The diameter of the window 124W is smaller than the inner diameter of the frame 21, and the outer diameter thereof is greater than the outer diameter of the frame 21. Therefore, when the cover 124 is lowered while the conveying carrier 20 is set on the stage 111 at a predetermined position, the cover 124 can cover the frame 21, with at least part of the semiconductor substrate 10 exposed from the window 124W.

The cover 124 is formed of, for example, a dielectric such as ceramics (e.g., alumina, aluminum nitride) or quarts, or a metal such as aluminum or aluminum with an anodic oxidation coating. The pressing members 107 can be formed of the aforementioned dielectric or metal, or a resin material.

After the conveying carrier 20 is passed onto the support members 122, a voltage is applied to the ESC electrode 119 from the DC power source 126. By doing this, the holding sheet 22 is brought into contact with the stage 111 and concurrently, is electrostatically chucked on the stage 111. The voltage application to the ESC electrode 119 may be initiated after the holding sheet 22 is set on (or comes in contact with) the stage 111.

Upon completion of etching, the gas in the vacuum chamber 103 is evacuated, and the gate valve opens. The conveying carrier 20 holding a plurality of element chips 200 is delivered out of the plasma processing apparatus 100 by means of a conveying system having entered through the gate valve. After the conveying carrier 20 is delivered out, the gate valve is immediately closed. The conveying carrier 20 may be delivered out by performing the above-mentioned procedures of setting the conveying carrier 20 on the stage 111 in the reverse order. Specifically, after the cover 124 is lifted to a predetermined position, the voltage applied to the ESC electrode 119 is cut off, to release the chucking of the conveying carrier 20 to the stage 111. Then, the support members 122 are raised. After the support members 122 reach a predetermined raised position, the conveying carrier 20 is delivered out of the vacuum chamber 103.

The conditions for generating a plasma (first plasma) used for etching the semiconductor layer may be set according to the material of the semiconductor layer and other factors.

The semiconductor layer is plasma-etched by, for example, a Bosch process. In the Bosch process, the semiconductor layer is etched vertically in the depth direction. When the semiconductor layer contains Si, the Bosch process repeats a film deposition step, a deposited-film etching step, and a Si etching step in this order, thereby to dig the semiconductor layer in the depth direction.

The film deposition step is carried out, for example, under the following conditions: while C₄F₈ is introduced as a process gas at a rate of 150 sccm or more and 250 sccm or less, the pressure in the vacuum chamber is controlled to 15 Pa or more and 25 Pa or less, with the input power to the first electrode from the first high-frequency source set at 1500 W or more and 2500 W or less, and the input power to the second electrode from the second high-frequency power source set at 0 W or more and 50 W or less; the processing time is 2 seconds or more and 15 seconds or less.

The deposited-film etching step is carried out, for example, under the following conditions: while SF₆ is introduced as a process gas at a rate of 200 sccm or more and 400 sccm or less, the pressure in the vacuum chamber is controlled to 5 Pa or more and 15 Pa or less, with the input power to the first electrode from the first high-frequency power source set at 1500 W or more and 2500 W or less, and the input power to the second electrode from the second high-frequency power source set at 300 W or more and 1000 W or less; the processing time is 2 seconds or more and 10 seconds or less.

The Si etching step is carried out, for example, under the following conditions: while SF₆ is introduced as a process gas at a rate of 200 sccm or more and 400 sccm or less, the pressure in the vacuum chamber is controlled to 5 Pa or more and 15 Pa or less, with the input power to the first electrode from the first high-frequency power source set at 1500 W or more and 2500 W or less, the input power to the second electrode from the second high-frequency power source set at 50 W or more and 500 W or less; the processing time is 10 seconds or more and 20 seconds or less.

By repeating the film deposition step, the deposited-film etching step, and the Si etching step under the conditions as above, the semiconductor layer containing Si can be etched vertically in the depth direction at a rate of 10 μm/min or more and 20 μm/min or less.

Although in the foregoing, a description is made on the element chip manufacturing method including a dicing step, a substrate processing method including an etching step, in place of the dicing step, is also encompassed in the present embodiment. In the etching step of the substrate processing method, after the second exposure step, the exposed semiconductor layer corresponding to the second region is etched with plasma. In this etching step, the semiconductor substrate is not diced, and grooves can be formed along the dicing regions on the semiconductor substrate.

The present disclosure is applicable to an element chip manufacturing method and a substrate processing method.

### REFERENCE NUMERALS

10: semiconductor substrate
   10a: notch
   10X: first principal surface
   10Y: second principal surface
   101: element region
   102: dicing region
   11: semiconductor layer
   15: alignment mark
   16: metal film
   R1: first region
   R2: second region
20: conveying carrier
   21: frame
      21a: notch
      21b: corner cut
   22: holding sheet
   22X: adhesive side
   22Y: non-adhesive side
40: protective film
100: plasma processing apparatus
   103: vacuum chamber
      103a: gas inlet
      103b: gas outlet
   108: dielectric member
   109: first electrode
   110A: first high-frequency power source
   110B: second high-frequency power source
   111: stage
   112: process gas source
   113: ashing gas source
   114: decompression system
   115: electrode layer
   116: metal layer
   117: base table
   118: peripheral member
   119: ESC electrode
   120: second electrode
   121: lifting rod
   122: support member
   123A: first lifting system
   123B: second lifting system
   124: cover
      124W: window
   125: coolant circulator
   126: DC power source
   127: coolant channel
   128: control unit
   129: circumferential ring
200: element chip
300: infrared camera

What is claimed is:

1. An element chip manufacturing method, comprising:
a preparation step of preparing a semiconductor substrate that includes a first layer having a first principal surface provided with a plurality of element regions, a dicing region defining the element regions, and an alignment mark, and a second layer laminated on the first layer and having a second principal surface opposite the first principal surface, wherein the first layer includes a semiconductor layer, and the second layer includes a metal film adjacent to the semiconductor layer;
a first exposure step of irradiating a first laser beam that is absorbed into the metal film, from the second principal surface side to a first region that corresponds to the alignment mark on the second principal surface, to remove the metal film corresponding to the first region and expose the semiconductor layer corresponding to the first region;
a smoothing step of smoothing a surface of the semiconductor layer corresponding to the first region exposed in the first exposure step;
a calculation step of imaging the semiconductor substrate from the second principal surface side, with a camera capable of sensing electromagnetic waves passing through the semiconductor layer, to detect a position of the alignment mark through the semiconductor layer corresponding to the first region, and then calculating a second region that corresponds to the dicing region on the second principal surface, based on the detected position of the alignment mark;
a second exposure step of irradiating a second laser beam to the second region from the second principal surface side, to remove the metal film corresponding to the second region and expose the semiconductor layer corresponding to the second region; and
a dicing step of removing the exposed semiconductor layer corresponding to the second region, after the second exposure step, to dice the semiconductor substrate into a plurality of element chips, wherein
in the smoothing step, the surface of the semiconductor layer corresponding to the first region exposed in the first exposure step is smoothed so as to have a surface roughness of ¼ or less of a wavelength of the electromagnetic waves.

2. The element chip manufacturing method according to claim 1, wherein in the smoothing step, the surface of the semiconductor layer corresponding to the first region exposed in the first exposure step is smoothed by exposing the surface to plasma.

3. The element chip manufacturing method according to claim 1, wherein in the smoothing step, the surface of the semiconductor layer corresponding to the first region exposed in the first exposure step is smoothed by striking particles against the surface.

4. The element chip manufacturing method according to claim 1, wherein in the smoothing step, the surface of the semiconductor layer corresponding to the first region exposed in the first exposure step is smoothed by polishing the surface.

5. The element chip manufacturing method according to claim 1, wherein in the smoothing step, the surface of the semiconductor layer corresponding to the first region exposed in the first exposure step is smoothed by irradiating a third laser beam to the surface.

6. The element chip manufacturing method according to claim 5, wherein the third laser beam has a pulse width larger than both a pulse width of the first laser beam and a pulse width of the second laser beam.

7. The element chip manufacturing method according to claim 5, wherein the third laser beam has a wavelength that is not absorbed into the metal film, and is absorbed into the semiconductor layer.

8. The element chip manufacturing method according to claim 1, wherein in the smoothing step, the surface of the semiconductor layer corresponding to the first region exposed in the first exposure step is smoothed by bringing the surface into contact with a chemical solution that dissolves the semiconductor layer.

9. A substrate processing method, comprising:
a preparation step of preparing a semiconductor substrate that includes a first layer having a first principal surface provided with a plurality of element regions, a dicing region defining the element regions, and an alignment mark, and a second layer laminated on the first layer and having a second principal surface opposite the first principal surface, wherein the first layer includes a semiconductor layer, and the second layer includes a metal film adjacent to the semiconductor layer;
a first exposure step of irradiating a first laser beam that is absorbed into the metal film, from the second principal surface side to a first region that corresponds to the alignment mark on the second principal surface, to remove the metal film corresponding to the first region and expose the semiconductor layer corresponding to the first region;
a smoothing step of smoothing a surface of the semiconductor layer corresponding to the first region exposed in the first exposure step;
a calculation step of imaging the semiconductor substrate from the second principal surface side, with a camera capable of sensing electromagnetic waves passing through the semiconductor layer, to detect a position of the alignment mark through the semiconductor layer corresponding to the first region, and then calculating a second region that corresponds to the dicing region on the second principal surface, based on the detected position of the alignment mark;
a second exposure step of irradiating a second laser beam to the second region from the second principal surface side, to remove the metal film corresponding to the second region and expose the semiconductor layer corresponding to the second region; and
an etching step of etching with plasma the exposed semiconductor layer corresponding to the second region, after the second exposure step, wherein
in the smoothing step, the surface of the semiconductor layer corresponding to the first region exposed in the first exposure step is smoothed so as to have a surface roughness of ¼ or less of a wavelength of the electromagnetic waves.
